(19) United States
(12) Patent Application Publication
(10) Pub. No.: US 2014/0061718 A1
(43) Pub. Date: Mar. 6, 2014

(54) INSULATED GATE BIPOLAR TRANSISTOR

(71) Applicant: SAMSUNG ELECTRO-MECHANICS CO., LTD., Suwon (KR)

(72) Inventors: In Hyuk SONG, Suwon (KR); Jae Hoon PARK, Suwon (KR); Dong Soo SEO, Suwon (KR)

(73) Assignee: SAMSUNG ELECTRO-MECHANICS CO., LTD., Suwon (KR)

(21) Appl. No.: 13/674,628

(22) Filed: Nov. 12, 2012

(30) Foreign Application Priority Data
Aug. 30, 2012 (KR) 10-2012-0095845

(51) Int. Cl. H01L 29/739

(52) U.S. Cl. CPC H01L 29/7395
USPC 257/139

(57) ABSTRACT

There is provided an insulated gate bipolar transistor, including: an active region including a gate electrode, a first emitter metal layer, a first well region, and one portion of a third well region; a termination region including a second well region supporting diffusion of a depletion layer; and a connection region located between the active region and the termination region and including a second emitter metal layer, a gate metal layer, and the other portion of the third well region, wherein the third well region is formed over the active region and the connection region, and the first emitter metal layer and the second emitter metal layer are formed on the third well region.

### CROSS-REFERENCE TO RELATED APPLICATIONS

This application claims the priority of Korean Patent Application No. 10-2012-0095846 filed on Aug. 30, 2012, in the Korean Intellectual Property Office, the disclosure of which is incorporated herein by reference.

### BACKGROUND OF THE INVENTION

1. Field of the Invention

The present invention relates to an insulated gate bipolar transistor.

2. Description of the Related Art

Recently, demand for a power conversion apparatus having reduced power consumption has increased. Therefore, research into a power semiconductor device playing a key role in the power conversion apparatus and having low power consumption has been actively conducted.

In particular, research into an insulated gate bipolar transistor (hereinafter, referred to as an ‘IGBT’) among power semiconductor devices, has been actively conducted. The reason is that the IGBT may reduce on voltage consumption due to a conductivity modulation effect and induce an increase in current density.

As current density is increased, saturation voltage may be decreased. Further, when current density is increased, a chip size is small for a chip consuming the same rated current and thus, chip manufacturing costs may be reduced.

As types of IGBT, there are provided a planar-type IGBT, a trench-type IGBT type, and the like. The planar-type IGBT has a structure in which gate electrodes are formed on a surface of a wafer. The trench type IGBT has a structure in which an oxide film is embedded in a trench vertically formed from the surface of the wafer and the gate electrodes are buried therein.

However, the insulated gate bipolar transistor may cause latch-up.

That is, a voltage drop may occur in a p-type well layer due to hole carriers injected from a p-type collector layer of the IGBT. The voltage drop in the p-type well layer induces an operation of a parasitic NPN transistor of the IGBT to cause latch-up.

It is known that latch-up generally only occurs in an active region.

However, as the IGBT is used as a high withstand voltage device, a width of a termination region is wide and therefore, latch-up may occur at a boundary between the active region and the termination region.

### RELATED ART DOCUMENT

(Patent Document 1) Korean Patent Laid-Open Publication No. 2012-008506

### SUMMARY OF THE INVENTION

An aspect of the present invention provides an insulated gate bipolar transistor capable of suppressing the occurrence of latch-up.

Another aspect of the present invention provides a metal mask shape for suppressing the occurrence of latch-up.

According to an aspect of the present invention, there is provided an insulated gate bipolar transistor, including: an active region including a gate electrode, a first emitter metal layer, a first well region, and one portion of a third well region; a termination region including a second well region supporting diffusion of a depletion layer; and a connection region located between the active region and the termination region and including a second emitter metal layer, a gate metal layer, and the other portion of the third well region, wherein the third well region may be formed over the active region and the connection region, and the first emitter metal layer and the second emitter metal layer may be formed on the third well region.

The active region, the termination region, and the connection region may include a collector metal layer, a collector layer formed on the collector metal layer, and a drift layer formed on the collector layer, and the first well region, the second well region, and the third well region may be formed on the drift layer.

The insulated gate bipolar transistor may further include a source layer formed on portions of top surfaces of the first well region and the third well region.

The third well region may be electrically connected to the first well region.

The insulated gate bipolar transistor may further include: a first gate poly electrode layer formed between the second emitter metal layer and the third well region and a second gate poly electrode layer formed between the gate metal layer and the third well region.

Thicknesses of the second well region and the third well region may be larger than that of the first well region.

The first emitter metal and the second emitter metal may be electrically connected to the second well region.

The second emitter metal may be formed at an outer side of the gate metal layer, and the first emitter metal layer may be formed at an inner side of the gate metal layer.

According to another aspect of the present invention, there is provided an insulated gate bipolar transistor, including: an active region including a gate electrode, a first well region, and one portion of a third well region; a termination region including a second well region supporting diffusion of a depletion layer; and a connection region connecting the active region and the termination region and including a gate metal layer and the other portion of the third well region; and an emitter metal layer formed in the active region and the connection region, wherein the emitter metal layer may be electrically connected to the third well region at a plurality of points.

The emitter metal layer may include a first emitter metal layer formed in the active region and a second emitter metal layer formed in the connection region, the second emitter metal layer may be formed at an outer side of the gate metal layer, and the first emitter metal layer may be formed at an inner side of the gate metal layer.

According to another aspect of the present invention, there is provided an insulated gate bipolar transistor, including: a collector metal layer; a collector layer formed on one surface of the collector metal layer; a drift layer formed on one surface of the collector layer; a first well region formed in an active region on one surface of the drift layer; a second well region formed in a termination region on one surface of the drift layer; a third well region formed in a connection region on one surface of the drift layer; a source region formed on portions of one surfaces of the first well region and the third well region; a gate electrode formed to penetrate through the source region and reach an interior of the drift layer; and an emitter metal layer electrically connected to the third well region at a plurality of points.

The emitter metal layer may include a first emitter metal layer formed in the active region and a second emitter metal layer formed in the connection region, the second emitter metal layer may be formed at an outer side of the gate metal layer, and the first emitter metal layer may be formed at an inner side of the gate metal layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a plan view schematically showing an insulated gate bipolar transistor according to an embodiment of the present invention, viewed from a top surface thereof;

FIG. 2 is a diagram schematically showing a cross-section of a portion A-A′ in the plan view of FIG. 1;

FIG. 3 is a circuit diagram showing a parasitic component of the insulated gate bipolar transistor;

FIG. 4 is a diagram showing a flow of hole carriers in a general insulated gate bipolar transistor; and

FIG. 5 is a diagram showing a flow of hole carriers in an insulated gate bipolar transistor according to an embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

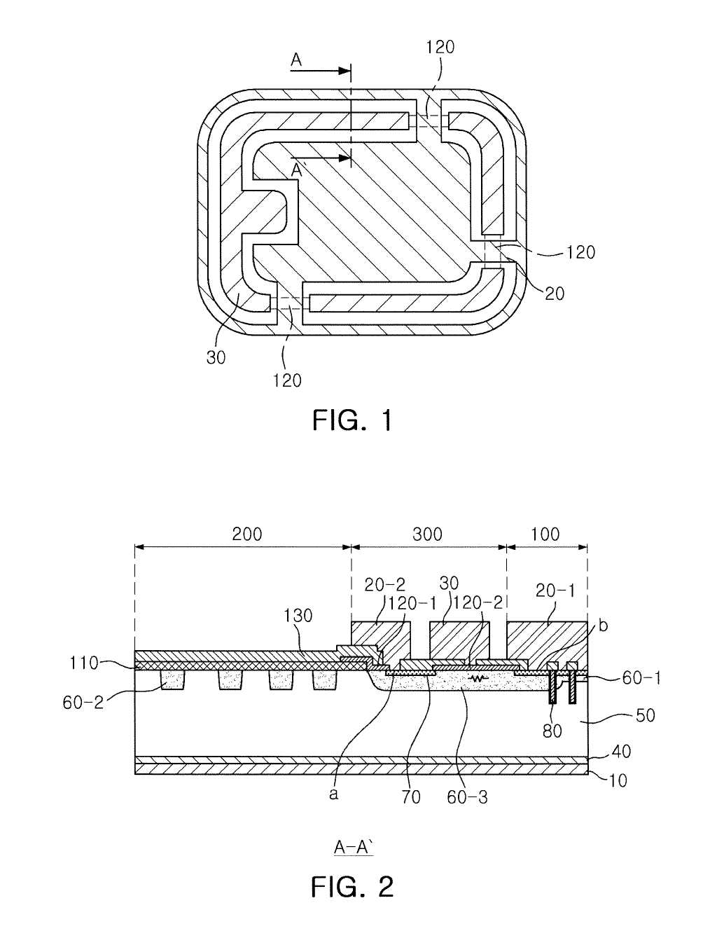

FIG. 1 is a plan view schematically showing an insulated gate bipolar transistor according to an embodiment of the present invention, viewed from a top surface thereof.

Referring to FIG. 1, the insulated gate bipolar transistor may include an emitter metal layer 20 and a gate metal layer 30 formed on top surface thereof.

The top surface of the insulated gate bipolar transistor may have a metal mask shape.

The emitter metal layer 20 is electrically connected to an emitter electrode formed under the emitter metal layer 20.

The emitter metal layer 20 is formed over a central portion and a periphery portion of the top surface of the insulated gate bipolar transistor.

The gate metal layer 30 may be electrically connected to a gate electrode to apply a gate voltage supplied from an external control circuit to a gate electrode.

The gate metal layer 30 may be formed between the central portion and the periphery portion of the top surface of the insulated gate bipolar transistor.

When being viewed from the top, the gate metal layer 30 may have a disconnected point. A portion of the emitter metal layer formed at the central portion of the top surface of the insulated gate bipolar transistor may be connected to another portion of the emitter metal layer formed at the periphery portion thereof through the disconnected point.

A gate poly electrode 120 is formed under the disconnected point of the gate metal layer. Even though it seems that the gate metal layer 30 have the disconnected point on the top surface of the insulated gate bipolar transistor, the gate metal layer 30 may be electrically connected through the gate poly electrode 120.

FIG. 2 is a diagram, schematically showing a cross-section of a portion A-A′ in the plan view of FIG. 1.

Referring to FIG. 2, a collector metal layer 10 may be formed under the insulated gate bipolar transistor.

A p-type collector layer 40 may be formed on one surface of the collector metal layer 10.

An n-type drift layer 50 may be formed on one surface of the p-type collector layer 40.

A p-type well region 60 may be formed on one surface of the n-type drift layer.

Meanwhile, in views of the overall insulated gate semiconductor device, an inner side may be defined as an active region 100.

Further, in views of the overall insulated gate semiconductor device, an outer side may be defined as a termination region 200.

In addition, a region located between the active region 100 and the termination region 200 may be defined as a connection region 300.

The connection region 300 may serve to smoothly diffuse a depletion layer generated in the active region 100 to the termination region 200.

The well region 60 may include a first well region 60-1, a second well region 60-2, and a third well region 60-3.

The first well region 60-1 may be formed in the active region 100 on one surface of the drift layer 50.

The second well region 60-2 may be formed in the termination region 200 on one surface of the drift layer 50.

The third well region 60-3 may be formed over the connection region 300 and the active region 100 on one surface of the drift layer 50.

The third well region 60-3 may be used as a termination ring.

When the third well region 60-3 is electrically isolated from the first well region 60-1, a reduction in withstand voltage occurs at the isolated portion due to an electric field concentration phenomenon. Therefore, in order to solve the defect, the third well region 60-3 may be electrically connected to the first well region 60-1.

Thicknesses of the second well region 60-2 and the third well region 60-3 may be greater than that of the first well region 60-1.

An n-type source region 70 may be formed on portions of one surfaces of the first well region 60-1 and the third well region 60-3.

A gate electrode 80 may be formed to penetrate through the n-type source region and reach the interior of the drift layer 50.

An insulating layer may surround the gate electrode 80.

The emitter metal layer 20 and the gate metal layer 30 may be formed on the third well region 60-3. The emitter metal layer 20 may include a first emitter metal layer 20-1 and a second emitter metal layer 20-2.

The first emitter metal layer 20-1 may mean an emitter metal layer formed in the active region 100. The second emitter metal layer 20-2 may mean an emitter metal layer formed in the connection region 300.

The first emitter metal layer 20-1 may be formed in an inner side of the gate metal layer 30 based on a position in which the gate metal layer 30 is formed. Further, the first emitter metal layer 20-2 may be formed in an outer side of the gate metal layer 30 based on the position in which the gate metal layer 30 is formed.

When the gate metal layer 30 and the first emitter metal layer 20-1 are disposed to be adjacent to each other, spikes may occur between respective electrodes. Therefore, an interval between the gate metal layer 30 and the first emitter metal layer 20-1 may be 10 μm or more.

According to the embodiment of the present invention, when being viewed from a cross-section of the insulated gate bipolar transistor, the emitter metal layer 20 may be electrically connected to the third well region 60-3 at a plurality of points.

Preferably, electrical connection points a and b of the emitter metal layer 20 and the third well region 60-3 may be provided at points corresponding to the inner side and the outer side of the gate metal layer 30.

A field oxide film 110 may be formed on top surfaces of the second well region 60-2 and a portion of the drift layer 50. Preferably, the field oxide film 110 may be formed in the termination region 200 and a portion of an outer side of the connection region 300.

A first gate poly electrode layer 120-1 may be formed between the second emitter metal layer 20-2 and the third well region 60-3.

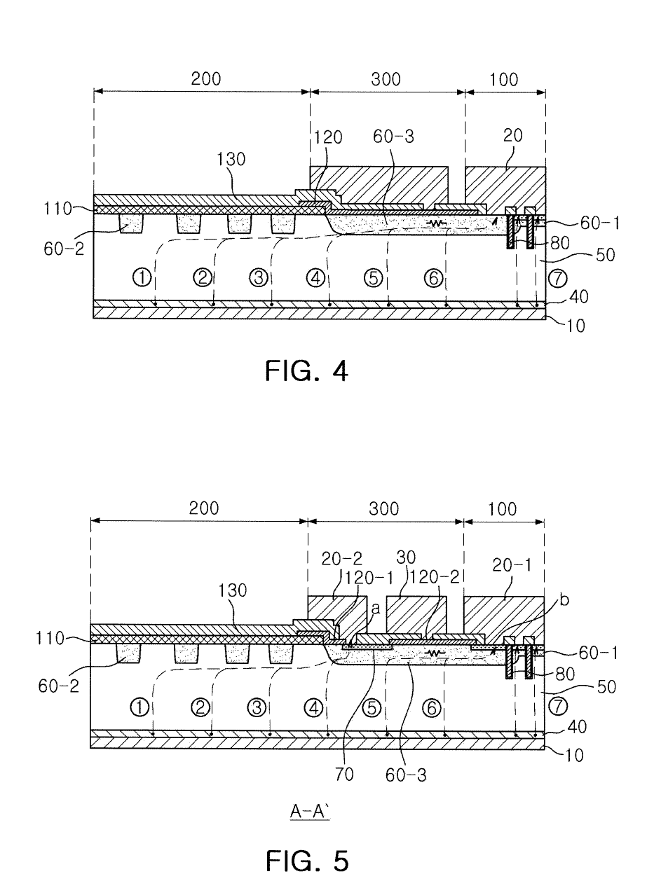

The first gate poly electrode layer 120-1 may serve as an electric field plate when withstand voltage (gate=0 V) is generated. Referring to FIG. 4, according to the related art, the gate poly electrode layer 120 contacts the gate metal layer 30.

According to the embodiment of the present invention, the first gate poly electrode layer 120-1 may contact the emitter metal layer 20-2. This is because that an emitter electrode is used as a ground electrode on an application circuit and therefore, does not cause a difference in characteristics from those of the existing structure.

Further, a second gate poly electrode layer 120-2 may be formed between the gate metal layer 30 and the third well region 60-3.

The second gate poly electrode layer 120-2 may have low resistance. Therefore, a width of the second gate poly electrode layer 120-2 may be 30 μm or more.

Further, an interlayer oxide 130 may be formed so as to prevent a connection between the respective layers.

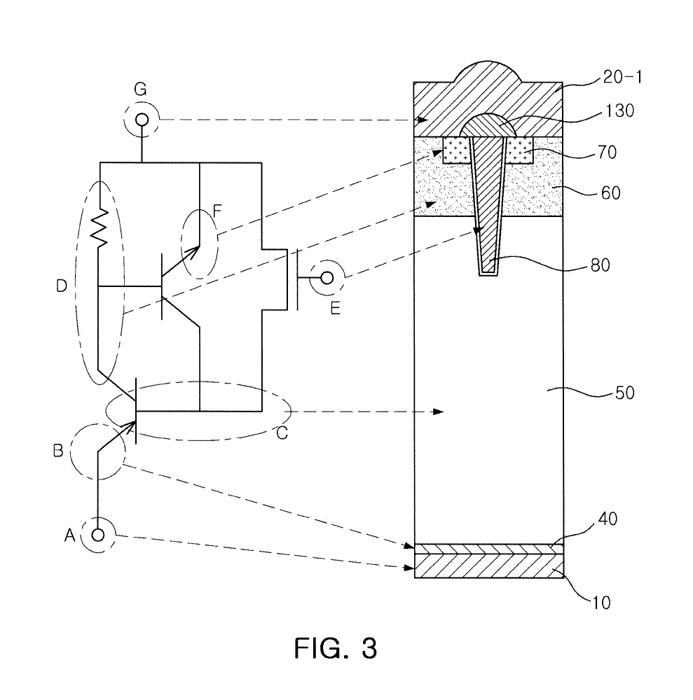

FIG. 3 is a circuit diagram showing a parasitic component of the insulated gate bipolar transistor.

Referring to FIG. 3, the collector metal layer 10 corresponds to an A region of the circuit diagram.

Further, the p-type collector layer 40 corresponds to a B region of the circuit diagram. Further, the n-type drift layer 50 corresponds to a C region of the circuit diagram. Further, the p-type well region 60 corresponds to a D region of the circuit diagram. That is, the p-type collector layer 40, the n-type drift layer 50, and the p-type well region 60 may form a PNP transistor.

Further, the n-type source region 70 corresponds to an F region of the circuit diagram. That is, the n-type drift layer 50, the p-type well region 60, and the n-type source region 70 may form a parasitic NPN transistor.

Further, the gate electrode 80 corresponds to an E region of the circuit diagram. Further, the emitter metal layer 20 corresponds to a G region of the circuit diagram.

Meanwhile, the p-type well region 60 means a resistance component in the circuit diagram of the IGBT.

In the case in which the insulated gate bipolar transistor (IGBT) is operated, voltage drop occurs when the hole carriers pass through the p-type well region 60. Further, when a voltage drop value is equal to or greater than built-in potential, the parasitic NPN transistor is operated. In this case, latch-up occurs in the insulated gate bipolar transistor (IGBT).

FIG. 4 is a diagram showing a flow of hole carriers in a general insulated gate bipolar transistor.

Referring to FIG. 4, at the ON operation of the IGBT, hole carriers injected from the p-type collector layer 40 in the active region 100 may transfer through the first well region 60-1 (\textcircled{7}).

However, hole carriers injected from the p-type collector layer 40 in the termination region 200 may transfer to the emitter metal layer 20 through the third well region 60-3, a path having the smallest resistance (\textcircled{1}, \textcircled{2}, or \textcircled{3}).

In this case, a hole carrier concentration in the third well region 60-3 is higher than that of in the first well region 60-1. Further, the path through which the hole carriers injected from the p-type collector layer 40 transfer (hereinafter, referred to as “transfer path of the hole carriers), in the termination region 200, is longer than that of the hole carriers injected from the p-type collector layer 40, in the active region 100.

Therefore, a great voltage drop occurs in the termination region 200, due to the hole carriers injected from the p-type collector layer 40.

Further, the hole carriers injected from the p-type collector layer 40 in the connection region 300 may transfer to the emitter metal layer 20 through the third well region 60-3, a path having the smallest resistance (\textcircled{4}, \textcircled{5}, or \textcircled{6}). Similarly, a considerable voltage drop occurs in the connection region 300, due to the hole carriers injected from the p-type collector layer 40.

Since the third well region 60-3 and the first well region 60-1 are electrically connected to each other, the voltage drop may affect latch-up. That is, when a voltage drop value is equal to or greater than built-in potential, latch-up may occur.

Further, when the insulated gate bipolar transistor is a withstand voltage device, a width of the termination region 200 is large and therefore, the occurrence of latch-up may increase.

FIG. 5 is a diagram showing a flow of hole carriers in the insulated gate bipolar transistor according to the embodiment of the present invention.

Referring to FIG. 5, at the ON operation of the IGBT, the hole carriers injected from the p-type collector layer 40 in the active region 100 may transfer through the first well region 60-1 (\textcircled{7}).

The hole carriers injected from the p-type collector layer 40 in the termination region 200 transfer to the emitter metal layer 20 through the third well region 60-3, a path having the smallest resistance (\textcircled{1}, \textcircled{2}, or \textcircled{3}).

Meanwhile, according to the embodiment of the present invention, when being viewed from a cross-section of the insulated gate bipolar transistor, the emitter metal layer 20 may be electrically connected to the third well region 60-3 at a plurality of points. For example, electrical connection points a and b of the emitter metal layer 20 and the third well region 60-3 may be provided at points corresponding to the inner side and the outer side of the gate metal layer 30.

In the case of the related art, the hole carriers injected from the p-type collector layer 40 in the termination region 200 are required to transfer to the predetermined electrical connection point b and therefore, a great voltage drop occurs.

According to the embodiment of the present invention, the hole carriers injected from the p-type collector layer 40 in the termination region 200 need not to transfer to the predetermined electrical connection point b.

That is, the hole carriers injected from the p-type collector layer 40 in the termination region 200 may be discharged to the emitter metal layer 20-2 through the electrical connection point to which the path thereof is more adjacent, as compared to the case of the electrical connection point b.

In other words, the insulated gate bipolar transistor according to the embodiment of the present invention has a structure of reducing the transfer path of the hole carriers generated in the termination region 200 to thereby reduce latch-up resistance.

In order to implement a high withstand voltage, even though the width of the termination region 200 is large, the transfer path of the hole carriers may be reduced and therefore, the voltage drop occurring at the boundary region between the termination region 200 and the active region 100 may be reduced to a level that can be ignored.

For adopting the structure, the metal mask shape shown in FIG. 1 may be used.

Referring to FIG. 1, the gate poly electrode 120 is formed under the disconnected point of the gate metal layer. Even though it seems that the gate metal layer 30 has a disconnection point on the top surface of the insulated gate bipolar transistor, the gate metal layer 30 may be electrically connected through the gate poly electrode 120.

The insulated gate bipolar transistor according to the embodiment of the present invention may be implemented using the metal mask shape.

As set forth above, according to the embodiments of the present invention, it is possible to provide the insulated gate bipolar transistor capable of suppressing the occurrence of latch-up.

Further, it is possible to provide the metal mask shape for suppressing the occurrence of latch-up to a user.

While the present invention has been shown and described in connection with the embodiments, it will be apparent to those skilled in the art that modifications and variations can be made without departing from the spirit and scope of the invention as defined by the appended claims.

What is claimed is:

1. An insulated gate bipolar transistor, comprising:
an active region including a gate electrode, a first emitter metal layer, a first well region, and one portion of a third well region;
a termination region including a second well region supporting diffusion of a depletion layer; and
a connection region located between the active region and the termination region and including a second emitter metal layer, a gate metal layer, and the other portion of the third well region,
wherein the third well region is formed over the active region and the connection region, and
the first emitter metal layer and the second emitter metal layer are formed on the third well region.

2. The insulated gate bipolar transistor of claim 1, wherein the active region, the termination region, and the connection region include a collector metal layer, a collector layer formed on the collector metal layer, and a drift layer formed on the collector layer, and
the first well region, the second well region, and the third well region are formed on the drift layer.

3. The insulated gate bipolar transistor of claim 1, further comprising a source layer formed on portions of top surfaces of the first well region and the third well region.

4. The insulated gate bipolar transistor of claim 1, wherein the third well region is electrically connected to the first well region.

5. The insulated gate bipolar transistor of claim 1, further comprising a first gate poly electrode layer formed between the second emitter metal layer and the third well region and a second gate poly electrode layer formed between the gate metal layer and the third well region.

6. The insulated gate bipolar transistor of claim 1, wherein thicknesses of the second well region and the third well region are larger than that of the first well region.

7. The insulated gate bipolar transistor of claim 1, wherein the first emitter metal layer and the second emitter metal layer are electrically connected to the second well region.

8. The insulated gate bipolar transistor of claim 1, wherein the second emitter metal layer is formed at an outer side of the gate metal layer, and
the first emitter metal layer is formed at an inner side of the gate metal layer.

9. An insulated gate bipolar transistor, comprising:
an active region including a gate electrode, a first well region, and one portion of a third well region;
a termination region including a second well region supporting diffusion of a depletion layer; and
a connection region connecting the active region and the termination region and including a gate metal layer and the other portion of the third well region; and
an emitter metal layer formed in the active region and the connection region,
wherein the emitter metal layer is electrically connected to the third well region at a plurality of points.

10. The insulated gate bipolar transistor of claim 9, wherein the emitter metal layer includes a first emitter metal layer formed in the active region and a second emitter metal layer formed in the connection region,
the second emitter metal layer is formed at an outer side of the gate metal layer, and
the first emitter metal layer is formed at an inner side of the gate metal layer.

11. An insulated gate bipolar transistor, comprising:
a collector metal layer;
a collector layer formed on one surface of the collector metal layer;
adrift layer formed on one surface of the collector layer;
a first well region formed in an active region on one surface of the drift layer;
a second well region formed in a termination region on one surface of the drift layer;
a third well region formed in a connection region on one surface of the drift layer;
a source region formed on portions of one surfaces of the first well region and the third well region;
a gate electrode formed to penetrate through the source region and reach an interior of the drift layer; and
an emitter metal layer electrically connected to the third well region at a plurality of points.

12. The insulated gate bipolar transistor of claim 11, wherein the emitter metal layer includes a first emitter metal layer formed in the active region and a second emitter metal layer formed in the connection region,
the second emitter metal layer is formed at an outer side of the gate metal layer, and
the first emitter metal layer is formed at an inner side of the gate metal layer.
